(19) United States
(12) Patent Application Publication
(10) Pub. No.: US 2007/0210434 A1
(43) Pub. Date: Sep. 13, 2007

(54) Structure of stacked integrated circuits and method for manufacturing the same

(76) Inventor: Chung Hsien Hsin, Hsinchu Hsien (TW)

Correspondence Address: PRO-TECHTOR INTERNATIONAL SERVICES, 20775 NORADA CT., SARATOGA, CA, 95070, US

(21) Appl. No.: 11/371,880

(22) Filed: Mar. 8, 2006

(51) Int. Cl. H01L 23/02

(52) U.S. Cl. 257/686

(57) ABSTRACT

The structure of stacked integrated circuits includes a substrate having an upper surface formed with first electrodes, and a lower surface formed with second electrodes. A lower integrated circuit is formed with bonding pads, and is located on the upper surface of the substrate. First adhered glue is coated on the periphery of the lower integrated circuit to form a plurality of points having same height. Second adhered glue is coated on the lower integrated circuit, and is located on the periphery of the first adhered glue. An upper integrated circuit has bonding pads, and is arranged on the lower integrated circuit, and is supported and is adhered by the first adhered glue and the second adhered glue. A plurality of wirings are electrically connected the bonding pads of the lower integrated circuit and the upper integrated circuit to the first electrodes of the substrate. And a compound layer is encapsulated on the upper integrated circuit and the lower integrated circuit.

### BACKGROUND OF THE INVENTION

1. Field of the Invention

The invention relates to a structure of stacked integrated circuits and method for manufacturing the same, in particular, to a structure of stacked integrated circuits in which integrated circuits can be effectively stacked so as to facilitate the manufacturing processes.

2. Description of the Related Art

In the current technological field, every product needs to be light, thin, and small. Therefore, it is preferable that the integrated circuit has a small volume in order to meet the demands of the products. In the prior art, even if the volumes of integrated circuits are small, they only can be electrically connected to the circuit board in parallel. Because the area of the circuit board is limited, it is not possible to increase the number of the integrated circuits mounted on the circuit board. Therefore, it is difficult to make the products small, thin, and light.

To meet the demands of manufacturing small, thin, and light products, a lot of integrated circuits can be stacked. However, when stacking a lot of integrated circuits, the upper integrated circuit will contact and press the wirings of the lower integrated circuit. In this case, the signal transmission to or from the lower integrated circuit is easily influenced.

Referring to FIG. 1, a structure of stacked integrated circuits includes a substrate 10, a lower integrated circuit 12, an upper integrated circuit 14, a plurality of wirings 16, and an isolation layer 18. The lower integrated circuit 12 is located on the substrate 10. The isolation layer 18 is located on the lower integrated circuit 12. The upper integrated circuit 14 is stacked on the isolation layer 18. That is, the upper integrated circuit 14 is stacked above the lower integrated circuit 12 with the isolation layer 18 interposed between the integrated circuits 12 and 14. Thus, a proper gap 20 is formed between the lower integrated circuit 12 and the upper integrated circuit 14. According to this structure, the plurality of wirings 16 can be electrically connected to the edge of the lower integrated circuit 12. Furthermore, the plurality of wirings 16 connecting the substrate 10 to the lower integrated circuit 12 are free from being pressed when stacking the upper integrated circuit 14 above the lower integrated circuit 12.

However, the above-mentioned structure has the disadvantages described hereinbelow. During the manufacturing processes, the isolation layer 18 has to be manufactured in advance, and then, it is adhered to the lower integrated circuit 12. Thereafter, the upper integrated circuit 14 has to be adhered on the isolation layer 18. As a result, the manufacturing processes are complicated, and the manufacturing costs are high.

To solve the above-mentioned problems, it is necessary for the invention to provide a structure of stacked integrated circuits in order to improve the stacking processes of the integrated circuits, facilitate the manufacturing processes, and lower down the manufacturing costs.

### SUMMARY OF THE INVENTION

It is therefore an object of the invention to provide a structure of stacked integrated circuits and method for manufacturing the same in order to effectively stack the integrated circuits and increase the manufacturing speed.

It is therefore another object of the invention to provide a structure of stacked integrated circuits and method for manufacturing the same in which the stacking processes can be simplified because an isolation layer can be simultaneously formed on the integrated circuit when coating the adhesive layer.

It is therefore still another object of the invention to provide a structure of stacked integrated circuits and method for manufacturing the same in which the adhesive layer and isolation layer can be formed simultaneously by a general coater. Thus, no other apparatus should be prepared for manufacturing the stacked integrated circuits.

According to one aspect of the invention, a structure of stacked integrated circuits includes

According to this structure, the present invention includes a substrate having an upper surface formed with first electrodes, and a lower surface formed with second electrodes. A lower integrated circuit is formed with bonding pads, and is located on the upper surface of the substrate. First adhered glue is coated on the periphery of the lower integrated circuit to form a plurality of points having same height. Second adhered glue is coated on the lower integrated circuit, and is located on the periphery of the first adhered glue. An upper integrated circuit has bonding pads, and is arranged on the lower integrated circuit, and is supported and is adhered by the first adhered glue and the second adhered glue. A plurality of wirings are electrically connected the bonding pads of the lower integrated circuit and the upper integrated circuit to the first electrodes of the substrate. And a compound layer is encapsulated on the upper integrated circuit and the lower integrated circuit.

### BRIEF DESCRIPTION OF THE DRAWINGS

FIG. 1 is a cross-sectional view showing a conventional structure of stacked integrated circuits.

FIG. 2 is a cross-sectional view showing a structure of stacked integrated circuits in accordance with one embodiment of the invention.

FIG. 3 is first schematic illustration showing the structure of stacked integrated circuits of the present invention.

FIG. 4 is second schematic illustration showing the structure of stacked integrated circuits in accordance with the present invention.

FIG. 5 is third schematic illustration showing the structure of stacked integrated circuits in accordance with the present invention.

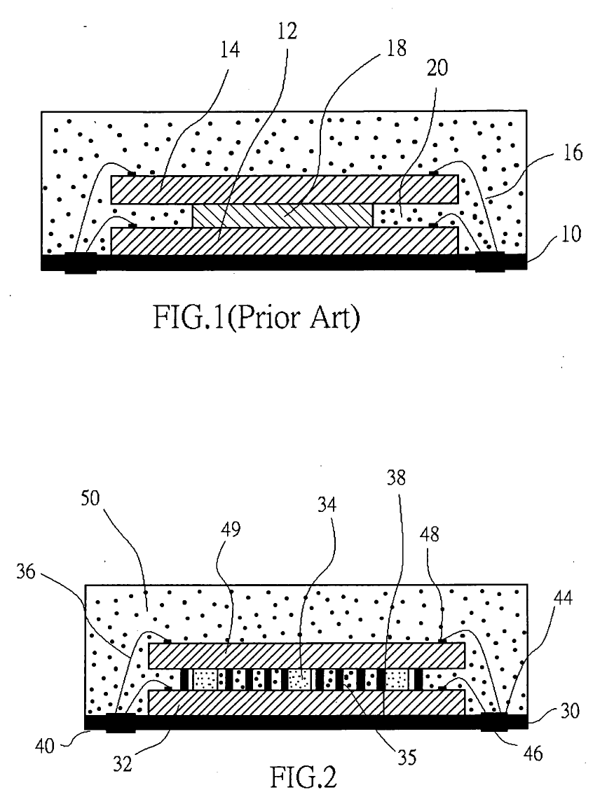

### DETAIL DESCRIPTION OF THE INVENTION

Referring to FIG. 2, the structure of stacked integrated circuits according to the invention includes a substrate 30, a lower integrated circuit 32, first adhered glue 34, second adhered glue 35, a plurality of wirings 36, an upper integrated circuit 49, and a compound layer 50.

The substrate 30 has an upper surface 38 formed with first electrodes 44, and a lower surface 40 formed with second electrodes 46.

The lower integrated circuit 32 is formed with bonding pads 48, and is located on the upper surface 38 of the substrate 30. The bonding pads 48 of the lower integrated circuit 32 are electrically connected to the first electrodes 44 of the substrate 30 by wires 36.

The first adhered glue 34 is coated on the periphery of the lower integrated circuit 32 for curing to form four points having same height.

The second adhered glue 35 is formed of epoxy, and is located on the lower integrated circuit 32, and is located on the periphery of the first adhered glue 34.

The upper integrated circuit 49 has bonding pads 48, and is arranged on the lower integrated circuit 32, and is supported and is adhered by the first adhered glue 34 and the second adhered glue 35.

The plurality of wirings 36 are electrically connected the bonding pads 48 of the lower integrated circuit 32 and the upper integrated circuit 49 to the first electrodes 44 of the substrate 30. And

The compound layer 50 is encapsulated on the upper integrated circuit 49 and the lower integrated circuit 32.

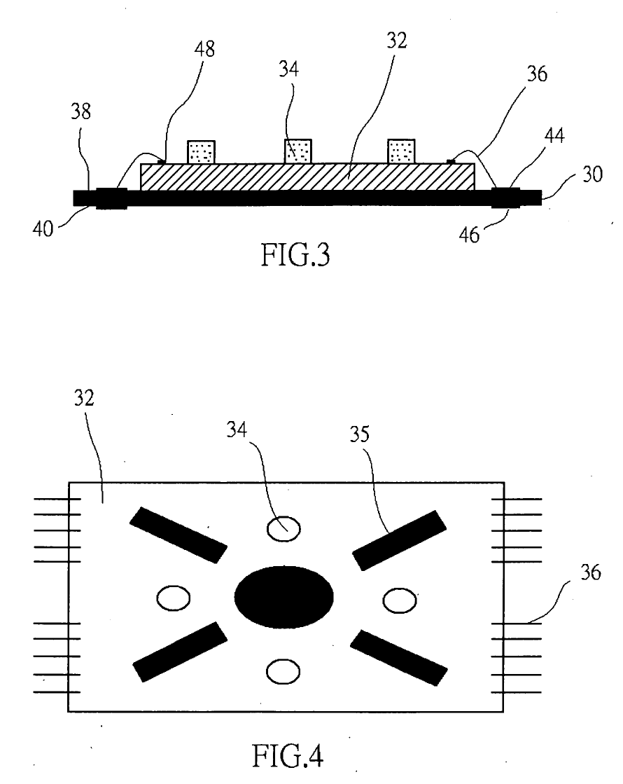

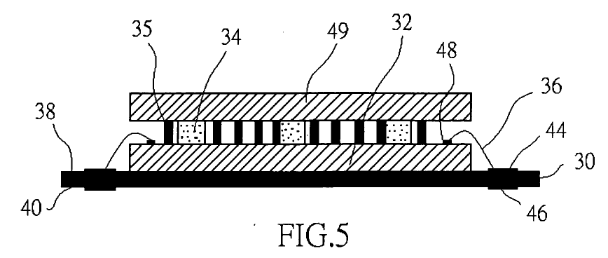

Referring to FIG. 3 and FIG. 4, it are schematic illustration showing a method for manufacturing a structure of stacked integrated circuits in accordance with the present invention, firstly providing a substrate 30 has an upper surface 30, which first electrodes 44 are formed on, and a lower surface 40, which second electrodes 46 are formed on.

Providing a lower integrated circuit 32 has bonding pads 48, and is located on the upper surface 38 of the substrate 30. The bonding pads 48 of the lower integrated circuit 32 are electrically connected to the first electrodes 44 of the substrate 30 by wires 36.

Providing first adhered glue 34 is coated on the four corner of the lower integrated circuit 32 to form four points having same height.

Providing second adhered glue 35 is formed of epoxy, and is located on the lower integrated circuit 32, and is located on the periphery of the first adhered glue 34.

Referring to FIG. 5, it is third schematic illustration showing a method for manufacturing a structure of stacked integrated circuits in accordance with the present invention, providing an upper integrated circuit 49, which is mounted on the lower integrated circuit 32, and is supported and is adhered by the first adhered glue 34 and the second adhered glue 35.

Providing wirings, which are electrically connected the bonding pads 48 of the upper integrated circuit 49 to the first electrodes 44 of the substrate 30. And

Providing a compound layer 50, which is encapsulated on the upper integrated circuit 49 and the lower integrated circuit 32.

While the invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A structure of stacked integrated circuits, comprising:
a substrate having an upper surface formed with first electrodes, and a lower surface formed with second electrodes;
a lower integrated circuit formed with bonding pads, and located on the upper surface of the substrate;
a first adhered glue coated on the periphery of the lower integrated circuit to form a plurality of points having same height;
a second adhered glue coated on the lower integrated circuit, and located on the periphery of the first adhered glue;
an upper integrated circuit having bonding pads, and arranged on the lower integrated circuit, and supported and adhered by the first adhered glue and the second adhered glue;
a plurality of wirings electrically connected the bonding pads of the lower integrated circuit and the upper integrated circuit to the first electrodes of the substrate; and
a compound layer encapsulated on the upper integrated circuit and the lower integrated circuit.

2. The structure of stacked integrated circuits according to claim 1, wherein the first adhered glue has four points formed on the four corner of the lower integrated circuit.

3. The structure of stacked integrated circuits according to claim 3, wherein the second adhered glue is formed of epoxy

4. A method for manufacturing a structure of stacked integrated circuits, comprising the steps of:
Providing a substrate having a upper surface formed with first electrodes, and a lower surface formed with second electrodes;
Providing a lower integrated circuit formed with bonding pads, and located on the upper surface of the substrate;
Providing first adhered glue coated on the periphery of the lower integrated circuit to form a plurality of points having same height;
Providing a plurality of wirings electrically connected the bonding pads of the lower integrated circuit to the first electrodes of the substrate;
Providing second adhered glue coated on the lower integrated circuit, and located on the periphery of the first adhered glue;
Providing an upper integrated circuit having bonding pads, and arranged on the lower integrated circuit, and supported and adhered by the first adhered glue and the second adhered glue;
Providing a plurality of wirings electrically connected the bonding pads of the upper integrated circuit to the first electrodes of the substrate; and
Providing a compound layer encapsulated on the upper integrated circuit and the lower integrated circuit.

5. The method for manufacturing a structure of stacked integrated circuits according to claim 4, wherein the first adhered glue has four points formed on the four corner of the lower integrated circuit to cure.

6. The method for manufacturing a structure of stacked integrated circuits according to claim 4, wherein the second adhered glue is formed of epoxy
